(19) United States
(12) Patent Application Publication
(10) Pub. No.: US 2016/0005707 A1
(43) Pub. Date: Jan. 7, 2016

(54) SEMICONDUCTOR PACKAGE AND METHOD OF MANUFACTURING THE SAME

(71) Applicant: Samsung Electronics Co., Ltd., Suwon-si (KR)

(72) Inventors: Yong-Hwan KWON, Suwon-si (KR); Myeong-Soon PARK, Goyang-si (KR); Chan-Ho LEE, Gwangmyeong-si (KR)

(21) Appl. No.: 14/754,686

(22) Filed: Jun. 29, 2015

(30) Foreign Application Priority Data
Jul. 2, 2014 (KR) 10-2014-0082448

(51) Int. Cl. H01L 23/00

(52) U.S. Cl. CPC H01L 24/17; H01L 24/81; H01L 24/11; H01L 2224/1712; H01L 2924/014; H01L 2924/1436

(57) ABSTRACT

A semiconductor package includes a package board that includes an circuit pattern and a plurality of contact pads electrically connected to the circuit pattern; a semiconductor chip having a plurality of chip pads; and a bump structure including a plurality of connecting bumps electrically connected with the semiconductor chip and the circuit pattern and a plurality of gap adjusting bumps bonded to the semiconductor chip and shaped into a slender bar between the semiconductor chip and the package board, the gap adjusting bumps spacing the semiconductor chip from the package board such that a gap space, S, is maintained between the package board and the semiconductor chip. A method of fabrication and a memory unit are disclosed.

### CROSS-REFERENCE TO RELATED APPLICATIONS

This application claims priority under 35 U.S.C. §119 to Korean Patent Application No. 10-2014-0082448 filed on Jul. 2, 2014 in the Korean Intellectual Property Office, the disclosure of which is incorporated by reference herein in its entirety.

### BACKGROUND

1. Field

Example embodiments relate to a semiconductor package and method of manufacturing the same, and more particularly, to a flip chip package and a method of manufacturing the flip chip package.

2. Description of the Related Art

The continuing demand for high performance electronics has brought about development of many improvements to packaging of semiconductor circuitry. In particular, a flip-chip package has been widely used in the semiconductor industry due to small size of the semiconductor package.

In conventional flip-chip packages, a plurality of bumps arranged on an active face of the semiconductor chip provide electrical contacts for access to the circuitry. During assembly, the chip is flipped onto a circuit board that includes corresponding electrical contacts. The bumps are then bonded to contact pads of the circuit board, thus bonding the semiconductor chip to the circuit board. Generally, a compressive mold is used in the bonding process to ensure connection with each chip pad on a circuit board. A gap space between the semiconductor chip and the circuit board is then filled with an electrically insulative and encapsulating material. The filling process is commonly referred to as “underfilling” with “under-fill” and/or encapsulating materials.

Unfortunately, applying compression to ensure adequate contact and connection may also cause a smaller gap space than desired. Insufficient flow of under-fill materials may be a direct result. This results in voids within the under-fill, which can lead to reduced mechanical strength as well as poor heat transfer. As one may imagine, excess compression may also cause improper interconnections and may render the circuitry useless.

Accordingly, there has been a need for an improved flip-chip package that reliably includes sufficient gap space between the chip and the circuit board to ensure mechanical and electrical reliability of the flip-chip package.

### SUMMARY

Exemplary embodiments provide a semiconductor package having a plurality of gap adjusting bumps for controlling the chip-board gap and having a sufficient minimal chip-board gap.

Some embodiments provide a method of manufacturing a semiconductor package.

According to exemplary embodiments, a semiconductor package includes a package board that includes an circuit pattern and a plurality of contact pads electrically connected to the circuit pattern; a semiconductor chip having a plurality of chip pads; and a bump structure having a plurality of connecting bumps electrically connected with the semiconductor chip and the circuit pattern and a plurality of gap adjusting bumps bonded to the semiconductor chip and shaped into a slender bar between the semiconductor chip and the package board, the gap adjusting bumps spacing the semiconductor chip from the package board such that a gap space, S, is maintained between the package board and the semiconductor chip.

For example, the semiconductor may include a passivation pattern covering an active face thereof and through which the chip pads may be exposed and the gap adjusting bump may include a slender body connected to the passivation layer and a sidewall solder member arranged on a sidewall of the slender body.

For example, the sidewall of the slender body may be shaped into a concave face that is directed to a center of the slender body and is covered with the sidewall solder member.

For example, the connecting bump may include a first conductive pillar body bonded to the chip pad and a first solder ball at an end portion of the first pillar body.

For example, the package board may include an insulation pattern covering an upper surface thereof and through which a plurality of the contact pads may be exposed and the connecting bump may be bonded to the contact pad via the first solder ball while the gap adjusting bump may be interposed between the passivation pattern and the insulation pattern and may make contact with the passivation pattern and the insulation pattern.

For example, the bump structure may include a plurality of supporting bumps bonded to the semiconductor chip and supporting the semiconductor chip on the package board.

For example, the circuit pattern may include at least a wiring line electrically connected to the contact pad and exposed through the insulation pattern and the supporting bump may include a second conductive pillar body bonded to the passivation pattern and a second solder ball positioned at an end portion of the second pillar body and bonded to the wiring line.

For example, the circuit pattern may be bonded to a single connecting bump and a plurality of the supporting bumps in such a configuration that the contact pad may be bonded to the connecting bump and the wiring line may be bonded to a plurality of the supporting bumps, and the gap adjusting bumps may be arranged on the insulation pattern without any interference with the connecting bumps and the supporting bumps.

For example, the slender body may have a height corresponding to the first pillar body and the second pillar body, so that the height of the slender body may be provided as the minimal gap distance between the semiconductor chip and the package board.

For example, the semiconductor package may further include an under-fill mold filling the gap space between the semiconductor chip and the package board.

For example, the minimal gap distance may be in a range of between 25 μm to 30 μm and the under-fill mold includes a plurality of fillers having a size in the range of between 20 μm to 24 μm.

For example, the semiconductor package may further include an additional semiconductor chip stacked on the semiconductor chip, and at least an inter-chip connector electrically connecting the semiconductor chip and the additional semiconductor chip.

For example, the inter-chip connector may include a penetration electrode penetrating through at least one of the semiconductor chip and the additional semiconductor chip and an inter-chip bump structure bonded to the penetration electrode.

For example, the inter-chip connector may include at least one re-directional line arranged on a rear surface of the semiconductor chip and bonded to the penetration electrode and the inter-chip bump structure.

According to other exemplary embodiments, there is provided a method of manufacturing a semiconductor package. A semiconductor chip may be provided in such a configuration that a plurality of chip pads and a passivation pattern may be formed on an active face and the chip pads may be exposed through the passivation pattern. A bump structure may be formed on the semiconductor chip such that the bump structure may include a plurality of protruding connecting bumps bonded to the chip pads, respectively, a plurality of protruding supporting bumps bonded to the passivation pattern and a plurality of slender-shaped gap adjusting bumps bonded to the passivation pattern. A package board may be provided to have at least one circuit pattern, at least one contact pad connected to the circuit pattern and an insulation pattern covering the circuit pattern such that the circuit pattern may include a wiring line connected to the contact pad and the contact pad and a portion of the wiring around the contact pad may be exposed through the insulation pattern. The semiconductor chip may be mounted onto the package board in such a manner that the connecting bump may be connected to a corresponding one of the contact pads and the supporting bump may be connected to the exposed wiring while the gap adjusting bumps may be arranged on the insulation pattern, thereby forming a chip-board combination having a gap space between the semiconductor chip and the package board at a minimal gap distance corresponding to a height of the gap adjusting bump. A transfer mold process may be conducted to the chip-board combination, thereby forming a molded under-fill (MUF) in the gap space simultaneously with an encapsulant enclosing the semiconductor chip.

For example, the bump structure may be formed on the semiconductor chip as follows: A seed layer and a mask layer may be sequentially formed on the chip pads and the passivation pattern. Then, the mask layer may be patterned into a mask pattern having a first opening through which the seed layer on the chip pad is partially exposed, a second opening through which the seed layer on the passivation pattern may be partially exposed and a slender-shaped recess through which the seed layer on the passivation pattern may be partially exposed into a slender shape. A first pillar body may be formed in a lower portion of the first opening, a second pillar body in a lower portion of the second opening and a slender body in a lower portion of the recess. A first solder may be formed in an upper portion of the first opening, a second solder in an upper portion of the second opening and a third solder in an upper portion of the recess. The mask pattern and the seed layer under the mask pattern may be removed from the semiconductor chip, thereby forming a preliminary connecting bump having a first seed pattern making contact with the chip pad, the first pillar body on the first seed pattern and the first solder on the first pillar body, a preliminary supporting bump having a second seed pattern making contact with the passivation pattern, the second pillar body on the second seed pattern and the second solder on the second pillar body, and a preliminary gap adjusting bump having a third seed pattern making contact with the passivation pattern, the third pillar body on the third seed pattern and the third solder on the third pillar body. A heat treatment may be performed to the preliminary connecting bump, the preliminary supporting bump and the preliminary gap adjusting bump, thereby forming the connecting bump having a first solder ball on the first pillar body, the supporting bump having a second solder ball on the second pillar body and the gap adjusting bump having a sidewall solder member on a sidewall of the slender body.

For example, the semiconductor chip may be mounted onto the package board by a soldering process for bonding the first solder ball to the contact pad and for bonding the second solder ball to the wiring line.

For example, the soldering process may be performed simultaneously with the heat treatment.

According to some additional embodiments, a plurality of gap adjusting bumps may be arranged on the package board along the peripheral portion of the semiconductor chip, and thus the semiconductor chip may be spaced apart from the chip board at a minimal gap distance corresponding to the height of the gap adjusting bump. Accordingly, the mold materials including minute fillers may be sufficiently flow into the gap space S to thereby reinforce the bonding force between the semiconductor chip and the package board while preventing the bridge defects caused by the solder compression of neighboring bumps in the transfer mold process.

In an additional embodiment, a memory package is provided. The memory package includes a memory unit that includes a semiconductor package that includes a package board that includes an circuit pattern and a plurality of contact pads electrically connected to the circuit pattern; a semiconductor chip with a plurality of chip pads; and a bump structure having a plurality of connecting bumps electrically connected with the semiconductor chip and the circuit pattern and a plurality of gap adjusting bumps bonded to the semiconductor chip and shaped into a slender bar between the semiconductor chip and the package board, the gap adjusting bumps spacing the semiconductor chip from the package board such that a gap space, S, is maintained between the package board and the semiconductor chip.

The memory unit may include a memory controller that may be configured for controlling data transfer between the memory unit and a host. The memory unit may be configured as one of a DRAM memory chip and a flash memory chip. The memory unit may be configured for use in one of a mobile system, a personal computer and a specialized system. The memory unit may include one of a single stack package and a multi stack package semiconductor package.

### BRIEF DESCRIPTION OF THE DRAWINGS

These and other features will become more apparent by describing in detail exemplary embodiments with reference to the accompanying drawings of which:

FIG. 1 is a cross-sectional view illustrating a semiconductor package in accordance with an exemplary embodiment;

FIG. 2A is a cross-sectional view of a semiconductor chip in the semiconductor package shown in FIG. 1;

FIG. 2B is a plan view of a package board in the semiconductor package shown in FIG. 1;

FIGS. 3A to 3C are perspective views of the bump structure in the semiconductor package shown in FIG. 1;

FIGS. 4, 5 and 7 to 9 are cross-sectional views illustrating processing steps for a method of manufacturing the semiconductor package shown in FIG. 1 in accordance with an exemplary embodiment;

FIGS. 6A to 6F are cross-sectional views illustrating detailed processing steps for a method of forming the bump structure on the semiconductor chip shown in FIG. 5 in accordance with an exemplary embodiment;

FIG. 10 is a cross-sectional view illustrating a semiconductor package in accordance with another exemplary embodiment;

FIG. 11 is a block diagram illustrating an exemplary memory card including semiconductor packages shown in FIG. 1 or 10; and

FIG. 12 is a block diagram illustrating an exemplary electronic system that includes the semiconductor package shown in FIG. 1 or 10.

### DETAILED DESCRIPTION OF THE EMBODIMENTS

Various exemplary embodiments will be described more fully hereinafter with reference to the accompanying drawings. The teachings herein may, however, be embodied in many different forms and should not be construed as limited to the embodiments set forth herein. Rather, embodiments disclosed herein are introductory, and will merely introduce concepts to those skilled in the art. In the drawings, the sizes and relative sizes of layers and regions may be exaggerated for clarity.

As discussed herein, the term “exemplary” is not meant to imply a superlative. Rather, the term “exemplary” merely refers to one of many possible embodiments.

It will be understood that when an element is referred to as being “on,” “connected to” or “coupled to” another element, the first element can be directly on, connected or coupled to the other element. Other intervening elements may be present. In contrast, when an element is referred to as being “directly on,” “directly connected to” or “directly coupled to” another element, there are no intervening elements included. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms.

These terms are only used to distinguish one element, component, region, layer or section from another region, layer or section. Thus, a first element, component, region, layer or section discussed could be termed a second element, component, region, layer or section without departing from the teachings of the present invention.

Spatially relative terms, terms of orientation and the like, such as “beneath,” “below,” “lower,” “above,” “upper” and the like, may be used herein for ease of description to describe one element in relationship to another element or elements. Such elements may (or may only partially be) illustrated in the figures. It will be understood that spatially relative terms are intended to encompass different orientations than those that are only depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle may, generally, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. Where any dispute of terminology and definitions is concerned, interpretations should be considered as is most favorable to the technology disclosed herein.

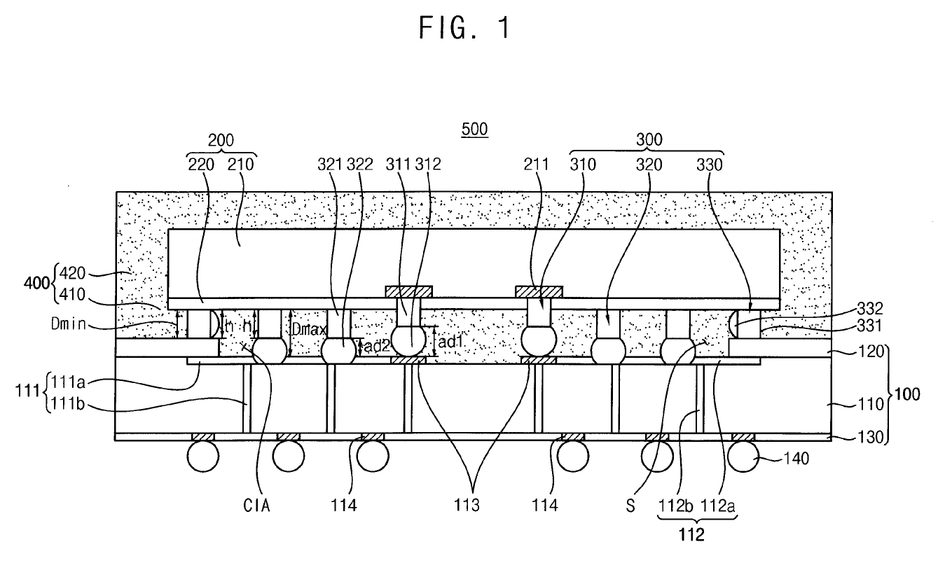

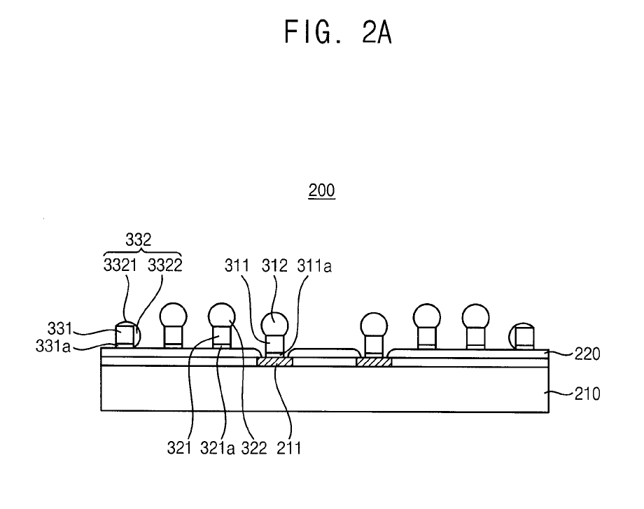

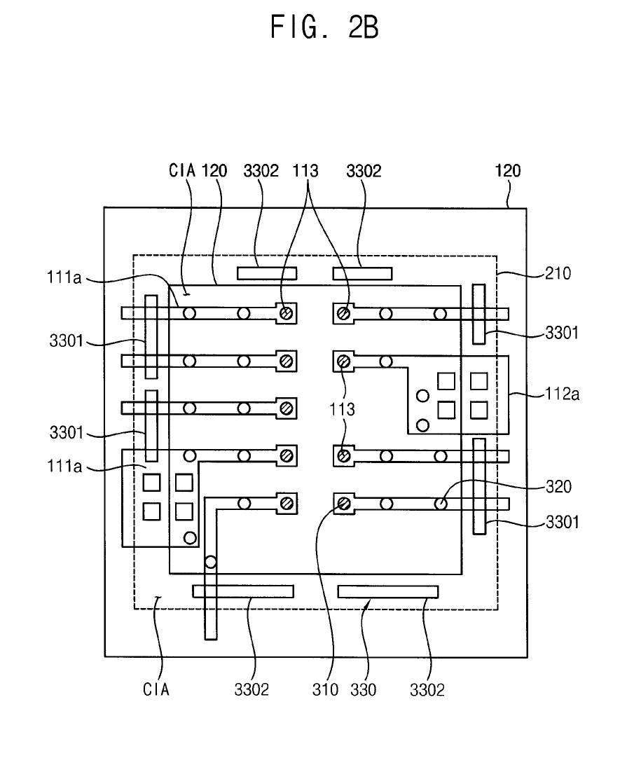

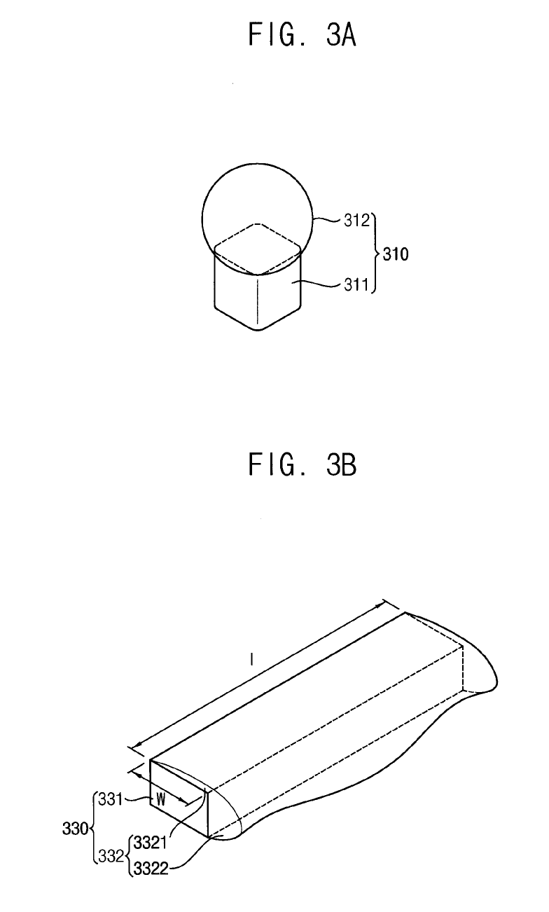

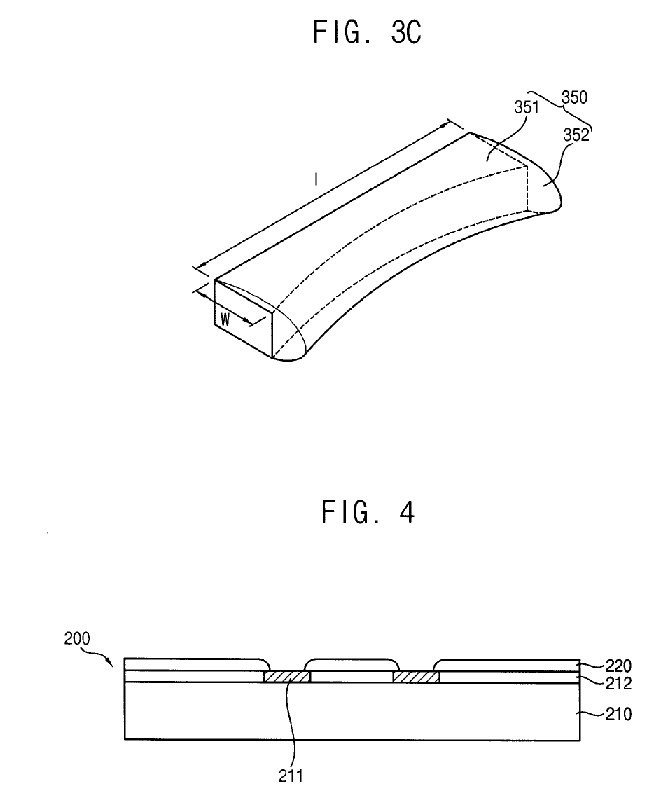

Hereinafter, example embodiments will be explained in detail with reference to the accompanying drawings. FIG. 1 is a cross-sectional view illustrating a semiconductor package in accordance with an exemplary embodiment. FIG. 2A is a cross-sectional view of a semiconductor chip in the semiconductor package shown in FIG. 1, and FIG. 2B is a plan view of a package board in the semiconductor package shown in FIG. 1. FIGS. 3A to 3C are perspective views of the bump structure in the semiconductor package shown in FIG. 1.

Referring to FIGS. 1, 2A and 2B, the semiconductor package 500 in accordance with a first embodiment may include a package board 100 having an electronic circuit pattern therein, a semiconductor chip 200 having a plurality of chip pads, a bump structure 300 interposed between the package board 100 and the semiconductor chip 200 with a mold layer 400 mechanically joining the semiconductor chip 200 to the package board 100.

The term “semiconductor chip” generally refers to electronic circuitry that is contained in a semiconductor component. Generally, each semiconductor chip includes a set of electronic circuits on a plate of semiconductor material such as silicon. In one example, a first chip includes a logic chip, such as a processor, while other chips may be memory chips connected that are then connected to the logic chip. A chip may include a variety of technologies, including, SSI, MSI, LSI, VLSI, WSI, SOC, 3D-IC and other technologies or forms as are known (or will be later devised) in the art.

In an exemplary embodiment, the package board 100 may include a printed circuit board (PCB) having a core 110 and a thin film providing a circuit pattern on at least one surface of the core 110. The core 110 may be shaped into a rigid plate and include insulating and heat-resistive materials such as glass fiber reinforced plastics and epoxy. The circuit pattern may include a power line for transmitting an electric power, a plurality of signal lines for communicating data signals and a ground line for electrically grounding the signal lines and the power line. In the present example, the circuit pattern may include a first pattern 111 functioning as the signal line and a second pattern 112 functioning as the power line and the ground line.

The circuit pattern may be coated on the surface of the core 110 as a single layer or a multilayer, and may include a plurality of wiring lines, such as first wiring lines 111a and second wiring lines 112a. The first wiring lines 111a and second wiring lines 112a generally extend along the surface of the core 110 and are connected to a plurality of first board plugs 111b and a plurality of second board plugs 112b. In the embodiments depicted, first wiring lines 111a and first board plugs 11b are associated with the first pattern, while second wiring lines 112a and second board plugs 112b are associated with the second pattern.

An upper insulation pattern 120 may be arranged on an upper surface of the core 110 and a lower insulation pattern 130 may be arranged on a lower surface of the core 110. Thus the circuit pattern on the core 110 may be protected from surroundings and may be electrically insulated from one another by the lower insulation pattern 120 and the upper insulation pattern 130. In some embodiments, the insulation patterns 120 and 130 may include a photo sensitive resin that includes photo epoxy and a photosensitive polymer such as a photo solder resist (PSR).

A plurality of contact pads 113 may be arranged on the upper surface of the package board 100 and may be electrically connected with the semiconductor chip 200. In addition, a plurality of board pads 114 may be arranged on the lower surface of the package board 100 and may make contact with a contact terminal 140 for contacting with external systems (not shown).

The contact pad 113 may be in contact with the chip pad 211 of the semiconductor chip 200 may be connected with at least a circuit pattern. The wiring line 111a of the circuit pattern may extend from the contact pad 113. The contact pad 113 may make direct contact with the wiring line 111a and 112a. In some embodiments, the contact pad 113 may make indirect contact with the wiring line 111a via a medium line such as a re-directional line. Particularly, the first pattern 111 may function as the signal line for the data transfer and may be provided as a single line, while the second pattern 112 may function as the power line and the ground line may be provided as a bundle of the wiring lines. The external system may be electrically connected to the circuit pattern via the board pad 114 and the contact terminal 140.

Therefore, the contact pad 113 and the board pad 114 may function as input/output ports of the package board 100 with an external system and the semiconductor chip 200 and may be combined into a single system in a medium of the package board 100. The contact pad 113 and the board pad 114 may include aluminum (Al), copper (Cu) and an alloy thereof and an electroplating layer including nickel (Ni)-silver (Ag) alloy may be coated on surfaces of the contact pad 113 and the board pad 114. Other materials and combinations of materials may be used as deemed appropriate. For example, in some embodiments, gold (Au) may be used.

The contact pad 113 and the board pad 114 may be exposed through the upper insulation pattern 120 and the lower insulation pattern 130, respectively. An upper insulation layer (not shown) may be formed on the upper surface of the core 110 and may be patterned into the upper insulation pattern through which the contact pad 113 may be exposed together with portions of wiring lines 111a and wiring lines 112a close to the contact pad 113. That is, the contact pad 113 may be wholly exposed through the upper insulation pattern 120 together with a first portion of wiring lines 111a and wiring lines 112a close to the contact pad 113, while a second portion of wiring lines 111a and wiring lines 112a relatively distant from the contact pad 113 may be covered with the upper insulation pattern 120. In such a case, some area of the upper insulation layer covering the contact pad 113 and the first portion of wiring lines 111a and wiring lines 112a may be removed from the core 110, while the upper insulation pattern 120 may have a chip interface area (CIA) through which the contact pad 113 and the first portion of wiring lines 111a and wiring lines 112a may exposed and thus the semiconductor chip 200 is bonded to the package board 100. Otherwise, the upper insulation layer may be patterned to have openings (not shown) through which the contact pad 113 and wiring lines 111a and wiring lines 112a may be individually exposed, so that the bump structure 300 may be connected to the contact pad 113 and wiring lines 111a and wiring lines 112a through the openings of the upper insulation pattern 120.

In this exemplary embodiment, the semiconductor chip 200 may include a center pad type flip chip structure in such a configuration that a plurality of the contact pads 113 is arranged in a line along a central portion of the core 110. Wiring lines 111a and wiring lines 112a may extend from the contact pad 113 toward a peripheral portion of the core 110. The central portion of the core 110 may be exposed through the upper insulation pattern 120 and as a result, the contact pad 113 and the first portion of the wiring lines 111a and 112a may be exposed through the upper insulation pattern 120 at the central portion of the core 110. In contrast, the peripheral portion of the core 110 may be covered with the upper insulation pattern 120 and as a result, the second portion of wiring lines 111a and wiring lines 112a may also be covered with the upper insulation pattern 120 at the peripheral portion of the core 110.

The lower insulation pattern 130 may cover the lower surface of the core 110 and may have a plurality of openings through which a plurality of the board pads 114 may be exposed, respectively. Thus, the board pads 114 may be electrically insulated from one another and be protected from surroundings by the lower insulation pattern 130. Each of the board pads 114 may be connected to the contact terminal 140 through the opening of the lower insulation pattern 130.

For example, the semiconductor chip 200 may include a chip body 210 having microelectronic devices on a semiconductor substrate (such as a wafer) and a plurality of chip pads 211 electrically connected to the microelectronic devices. The semiconductor chip 200 may include a passivation pattern 220 covering the chip body 210 in such a way that the chip pad 211 may be exposed through the passivation pattern 220. The semiconductor chip 200 may include a memory chip such as a dynamic random access memory (DRAM) device and a flash memory device and a logic chip.

While the present example embodiment discloses a center pad chip in which the chip pads 211 may be arranged at a central portion of the chip body 210, this is not limiting. For example, an edge pad chip in which the chip pads are arranged at an edge portion of the chip body 210 may also be used for the semiconductor chip 200. The chip pad 211 may include a conductive metal such as copper (Cu) and aluminum (Al) and the passivation pattern 220 may include a photosensitive resin such as photosensitive polyimide (PSPI).

The chip pads 211 arranged on an active face of the semiconductor chip 200 may face the package board 100. The bump structure 300 may be arranged between the chip pads 211 and the package board 100, thus the semiconductor chip 200 may be mechanically combined and electrically connected to the package board 100 by the bump structure 300 as the flip chip structure.

More specifically, and as an example, when assembled, the bump structure 300 may include a plurality of connecting bumps 310 electrically connected with the semiconductor chip 200 and the circuit pattern of the package board 100. The bump structure 300 further includes a plurality of supporting bumps 320 bonded to the semiconductor chip 200 and supporting the semiconductor chip 200 on the package board 100 as well as a plurality of gap adjusting bumps 330 bonded to the semiconductor chip 200 and shaped into a slender bar between the semiconductor chip 200 and the package board 100. The gap adjusting bumps 330 provide for spacing the semiconductor chip 200 from the package board 100 at a gap distance such that a gap space, S, for receiving the connecting bumps 310 is maintained between the package board 100 and the semiconductor chip 200 irrespective of external forces.

Each of the connecting bumps 310 may be connected with a respective one of the chip pad 211s and the contact pads 113, so that the semiconductor chip 200 may be electrically connected to the circuit pattern of the package board 100. Thus, the contact terminal 140 may be electrically connected to the semiconductor chip 200 via the first patterns 111 and the second patterns 112 of the circuit pattern and the connecting bump 310.

In addition, the connecting bumps 310 may improve the mechanical bonding force between the semiconductor chip 200 and the package board 100 in the flip chip structure. The semiconductor chip 200 may be bonded to the package board 100 by the connecting bumps 310 in such a way that the semiconductor chip 200 may be spaced apart from the package board 100 by a height of the connecting bumps 310. Thus, a gap space, S, may exist between the package board 100 and the semiconductor chip 200. Under-fill materials may be provided into the gap space, S, and the semiconductor chip 200 may be secured to the package board with high reliability. Particularly, the gap space, S, between the semiconductor chip 200 and the package board 100 may be minimally maintained in a mold under-fill process, because the semiconductor chip 200 may be spaced apart from the package board 100 by the minimal gap distance due to the gap adjusting bump 330 which will be described in detail hereinafter.

Each connecting bump 310 may include a first pillar body 311 bonded to the chip pad 211 and include electrically conductive materials. When assembled, a first solder ball 312 is interposed between an upper portion of the first pillar body 311 and the contact pad 113. The first pillar body 311 may be bonded to the contact pad 113 by the first solder ball 312. The first pillar body 311 may include conductive metals such as copper (Cu) and aluminum (Al). A first seed pattern 311a may be further interposed between the first chip pad 211 and the first pillar body 311 as a seed layer for a plating process. In addition, the first seed pattern 311a may function as a barrier pattern for preventing the metals for the first pillar body 311 from diffusing into the chip pad 211.

As shown in FIG. 2B, since the semiconductor chip 200 may include a center pad structure, the plurality of connecting bumps 310 may be arranged in a line along a central portion of the semiconductor chip 200 and a plurality of the contact pads 113 may also be arranged in a line correspondently to the connecting bumps 310. The arrangement of the contact pads 113 may be provided in various configurations of the semiconductor package 500. For example, a variety of connecting patterns such as re-directional lines may be used. The wiring lines 111a and 112a of the first pattern 111 and the second pattern 112 may extend at a peripheral portion of the package board 100 and may be connected to the contact pad 113 that may be arranged at a central portion of the package board 100.

In embodiments where the semiconductor chip 200 includes an edge pad structure, the connecting bumps 310 may be arranged at the peripheral portion of the semiconductor chip 200 and thus the contact pads 113 may also be arranged at the peripheral portion of the semiconductor chip 200. In such a case, the wiring lines 111a and 112a may extend to the central portion from the peripheral portion of the semiconductor chip 200.

The supporting bumps 320 may be bonded to the passivation pattern 220 of the semiconductor chip 200 and may support the semiconductor chip 200 on the package board 100. For example, each supporting bump 320 may include a second pillar body 321 bonded to the passivation pattern 220 and a second solder ball 322 interposed between the second pillar body 321 and the wiring lines 111a and 112a. The second pillar body 321 may be bonded to the wiring lines 111a and 112a via the second solder ball 322.

In the present exemplary embodiment, the supporting bump 320 functions as a dummy that is provided for mechanically supporting the semiconductor chip 200. That is, the supporting bump 320 does not provide for electrical connection between the semiconductor chip 200 and the circuit pattern of the package board 100. In addition, since the semiconductor chip 200 of the present example embodiment may include the center pad structure, the plurality of the supporting bumps 320 may extend in a line from the central portion to the peripheral portion of the semiconductor chip 200.

The supporting bump 320 may be landed or secured to the wiring lines 111a and 112a. Thus, the wirings lines 111a and 112a may function as a securing land, so that no additional securing land may be needed for the supporting bumps.

The second pillar body 321 may have the same height as the first pillar body 311. However, since the first pillar body 311 may be bonded to the chip pad 211 and the second pillar body 321 may be bonded to the passivation pattern 220, the second pillar body 321 may be closer to the package board 100 than the first pillar body 311 as long as the thickness of the passivation pattern 220. In the present example embodiment, the first pillar bodies 311 and the second pillar bodies 321 may include conductive materials and the first solder balls 312 and the second solder balls 322 also include the same or substantially similar conductive materials. In some embodiments, the first pillar bodies 311 and the second pillar bodies 321 include different materials, and the first solder balls 312 and the second solder balls 322 may also include different materials. In some embodiments, different materials may be called for according to the processing conditions and requirements of the semiconductor package 500. In addition, the supporting bump 320 may have greater size than the connecting bump 310, because the supporting bump 320 may support the semiconductor chip 200 instead of electrically connecting the semiconductor chip 200.

As shown in FIG. 3A, the first pillar bodies 311 and the second pillar bodies 321 may be shaped into a hexahedron and the first solder balls 312 and the second solder balls 322 may be shaped into a ball due to a surface tension in a reflow process.

Particularly, the upper insulation pattern 120 may be partially removed from the core 110 of the package board 100 in such a way that the contact pad 113 and the wiring lines 111a and 112a may be exposed, so that a chip interface area, CIA, may be prepared on the package board 100. Thus, the connecting bumps 310 and the supporting bumps 320 may be bonded to the contact pads 113 and the wiring lines 111a and 112a that may be exposed in the chip interface area, CIA.

In some embodiments, at least one connecting hole (not shown) and at least one supporting hole (not shown) may be provided with the upper insulation pattern 120. The upper insulation pattern 120 covering the contact pad 113 may be partially exposed to thereby form the connecting hole through which the contact pad 113 may be exposed and the connecting bump 310 may be positioned in the connecting hole. In the same way, the upper insulation pattern 120 covering the wiring lines 111a and 112a may be partially exposed to thereby form the supporting hole through which the wiring lines 111a and 112a may be exposed and the supporting bump 320 may be positioned in the supporting hole. In such a case, the neighboring connecting bumps 310 may be electrically insulated from each other by the upper insulation pattern 120 and the neighboring supporting bumps 320 may be electrically insulated from each other by the upper insulation pattern 120.

The gap adjusting bump 330 may be interposed between the passivation pattern 220 of the semiconductor chip 200 and the upper insulation pattern 120 of the package board 100 and may space the semiconductor chip 200 from the package board 100 at the minimal gap distance. Therefore, the gap space, S, may be sufficiently provided between the semiconductor chip 200 and the package board 100, thereby providing a sufficient mold flow space in the mold under-fill process and preventing the connecting bumps 310 and/or the supporting bumps 320 adjacent to each other from being connected into a bridge defect of the bump structure 300 due to the external forces such as compressive forces in the mold under-fill process.

As shown in FIG. 3B, the gap adjusting bump 330 may include a slender body 331 bonded to the passivation pattern 220 and including conductive materials and a sidewall solder member 332 bonded to a sidewall of the slender body 331.

The slender body 331 may be shaped into a rod member having a length, L, that is much greater than a width, W, thereof. The slender body 331 may be bonded to the passivation pattern 220 at the peripheral portion of the semiconductor chip 200. The first pillar bodies 311 and the second pillar bodies 321 may be differentiated from the slender body 331 in a variety of ways. For example, the slender body 331 may exhibit a length, L, and width, W, that is limited within some ranges to be formed into the hexahedron. In the present example embodiment, the slender body 331 may include the same conductive materials as the first and the second pillar bodies 311 and 321 in the same process, so that first seed pattern 311a, second seed pattern 321a and third seed pattern 331a may be interposed between the passivation pattern 220 and the first pillar body 311, the second pillar body 321 and the slender body 331, respectively. The first, second and third seed patterns 311a, 321a and 331a may reinforce the adhesive forces between the passivation pattern 220 and the bump structure 300 and may prevent the diffusion of the conductive materials.

Solder materials may be positioned on a top surface of the slender body 331 and may flow down across the top surface and sidewall of the slender body 331 in reflow process to the solder materials. Thus, most of the solder materials may be positioned on the sidewall of the slender body 331 and residuals of the solder materials may remain on the top surface of the slender body 331, thereby forming the sidewall solder member enclosing the slender body 331. Thus, the sidewall solder member 332 may include a thin solder 3321 remaining on the top surface of the slender body 331 without flowing downwards and a thick solder 3322 flowed down from the top surface and positioning on the sidewall of the slender body 331.

When the semiconductor chip 200 may be compressed toward the package board 100 in the mold under-fill process for forming the under-fill mold 410 in the gap space, S, the slender body 331, which may include harder conductive metals which may resist against the compressive forces and thus the gap distance between the semiconductor chip 200 and the package board 100 may be maintained at a minimal degree corresponding to the height of the slender body 331. That is, the semiconductor chip 200 may be spaced apart from the package board 100 at the minimal gap distance corresponding to the height of the gap adjusting bump 330. Further, the under-fill materials may flow with sufficiently reduced interrupts in the gap space, S, so that under-fill mold defects such as voids may be sufficiently reduced in the under-fill mold 410.

Flow characteristics of the solder materials in the reflow process may be varied according to the shapes and configurations of the body on which the solder materials may be positioned. The first and the second pillar bodies 311 and 321 may be shaped into the hexahedron in which the ratio of length, L, to width, W, may not be sufficiently great, thus the solder materials on the first pillar bodies 311 and the second pillar bodies 321 may be agglomerated into a ball shape, and may be restricted from flowing downwards due to the surface tension in the reflow process. In contrast, the slender body 331 may be shaped into the rod member in which the ratio of length, L, to width, W, may be sufficiently great, thus the solder materials on the slender body 331 may flow downwards along the sidewall in the reflow process and may be formed into a lump of the solder materials on the sidewall of the slender body 331. Therefore, a little bit of the solder materials may remain on the slender body 331 and most of the solder materials may be positioned on the sidewall of the slender body 331 as the sidewall solder member 332.

Since the top surface of the slender body 331 may make substantial contact with the upper insulation pattern 120 of the package board 100 and the slender body 331 may be sufficiently resistive to the compressive forces that may be applied to the semiconductor chip 200 in the mold under-fill process, the gap distance between the semiconductor chip 200 and the package board 100 may not be reduced below the height of the slender body 331. That is, the minimal gap distance, Dₘᵢₙ, may be maintained between the semiconductor chip 200 and the package board 100 in the mold under-fill process. In the present example embodiment, the ratio of length, L, to width, W, of the slender body 331 may be in a range of about three (3) to about five (5). However, this range is illustrative for the exemplary embodiment and is not to be construed as limiting thereof.

The shape or configuration of the slender body 331 may be modified for increasing the solidification of the solder materials on the sidewall of the slender body 331.

As shown in FIG. 3C, a modification of the gap adjusting bump 350 may include a modified slender body 351 bonded to the passivation pattern 220 and having a concaved sidewall, which may be directed to a center of the slender body 351, and a modified sidewall solder member 352 on the concaved sidewall of the modified slender body 351.

The solder materials may flow down onto the concaved sidewall of the modified slender body 351 in the reflow process and may be uniformly formed into the modified sidewall solder member 352 having a concaved shape according to the concaved sidewall of the modified slender body 351.

In the present example embodiment, a plurality of the contact pads 113 may be arranged along the central portion of the semiconductor chip 200 and may be connected to the connecting bumps 310 by one to one. The wiring lines 111a and 112a may extend from each of the contact pads 113 to the peripheral portion of the semiconductor chip 200. Each of the wiring lines 111a and 112a may be bonded to a plurality of the supporting bumps 320. Therefore, a single circuit unit including a single contact pad 113 and a single wiring line 111a, 112a may be connected to a single connecting bump 310 and a plurality of the supporting bumps 320. The gap adjusting bump 330 may be interposed between the passivation pattern 220 and the upper insulation pattern 120 without any interference with the connecting bumps 310 and the supporting bumps 320.

Particularly, the slender body 331 may have substantially the same height, H, as the first and the second pillar bodies 311 and 321, thus the semiconductor chip 200 may be spaced apart from the package board 100 by the minimal gap distance, Dₘᵢₙ, corresponding to the height, H, of the slender body 331.

Since the first pillar body 311 may be bonded to the chip pad 211 under the passivation pattern 220, a top end portion of the first pillar body 311 may be spaced apart from the contact pad 113 by a first adhesive distance. In the same way, since the second pillar body 321 may be bonded to the passivation pattern 220, a top end portion of the second pillar body 321 may be spaced apart from wiring line 111a or wiring line 112a by a second adhesive distance. The first solder ball 312 may be interposed between the first pillar body 311 and the contact pad 113 to cover the first adhesive distance and the second solder ball 322 may be interposed between the second pillar body 321 and the wiring lines 111a and 112a to cover the second adhesive distance. Thus, the size of the first solder ball 312 may be larger than that of the second solder ball 322.

The slender body 331 may make direct contact with the upper insulation pattern 120 without an adhesive distance and the solder materials may be positioned on the sidewall of the slender body 331 as the sidewall solder member 332. Therefore, the semiconductor chip 200 may be spaced apart from the package board 100 in a range from the minimal gap distance, Dₘᵢₙ, corresponding to the height, H, of the slender body 331 to a maximal gap distance, Dₘₐₓ, corresponding to the sum of the height, H, of the second pillar body 321 and the second adhesive distance.

The slender body 331 may include conductive metals and thus may sufficiently resist against the compressive force to the semiconductor chip 200 toward the package board 100 in the mold under-fill process. Therefore, the semiconductor chip 200 may be spaced apart from the package board 100 by the minimal gap distance, Dₘᵢₙ, in spite of the compressive force in the mold under-fill process.

In the present example embodiment, the height, H, of the first pillar body 311 and the second pillar body 321 and the slender body 331 may be in a range of about 25 μm to about 30 μm, so that the semiconductor chip 200 may be spaced apart from the package board 100 by the minimal gap distance, Dₘᵢₙ, of about 25 μm to about 30 μm.

The mold layer 400 may mechanically combine the semiconductor chip 200 to the package board 100 and may protect the semiconductor chip 200 and the bump structure 300 from surroundings.

For example, the mold layer 400 may include an under-fill mold 410 filling the gap space, S, between the semiconductor chip 200 and the package board 100 and an encapsulant 420 covering the semiconductor chip 200 on the package board 100.

In the present example embodiment, the under-fill mold 410 may include a molded under-fill (MUF) in the gap space, S, that may be formed by a transfer mold process. The combination of the semiconductor chip 200 and the package board 100 may be located in a cavity of a transfer mold and liquefied or sol state epoxy mold compounds (EMC) may be injected into the cavity of the transfer mold. Thus, the under-fill mold 410 may be formed in the gap space, S, under the semiconductor chip 200 together with the encapsulant 420 enclosing the semiconductor chip 200. Particularly, when a plurality of the semiconductor chips 200 may be mounted on a large-sized single package board 100, the under-fill mold 410 may be provided for each of the gap spaces, S, between each semiconductor chip and the large-sized single package board.

In the transfer mold process, the epoxy mold compounds, EMC, may be injected into the gap space, S, together with a plurality of solid fillers for improving bonding force of the semiconductor chip 200 to the package board 100. Therefore, in instances when the semiconductor chip 200 is excessively compressed toward the package board 100 and thus the gap distance between the semiconductor chip 200 and the package board 100 is excessively reduced in the transfer mold process, the solid filler in the epoxy mold compounds, EMC, may not be sufficiently supplied into the gap space, S. As a result, the mechanical bonding force between the semiconductor chip 200 and the package board 100 may be weaker than desired. However, since the minimal gap distance Dₘᵢₙ may be provided between the semiconductor chip 200 and the board 100 due to the gap adjusting bump 330 in the present example embodiment, the solid filler in the epoxy mold compounds, EMC, may be sufficiently provided into the gap space, S, in spite of the compressive forces to the semiconductor chip 200 in the transfer mold process, thereby preventing the insufficient filler supply in the transfer mold process and improving bonding force of the semiconductor chip 200 to the package board 100.

Since most of the solid fillers in the epoxy mold compounds, EMC, may be shaped into a ball having a diameter smaller than about 24 μm and the height, H, of the slender body 331 may be in a range of about 25 μm to about 30 μm, the solid fillers may be surely injected into the gap space, S, and thus the insufficient filler supply may be sufficiently prevented in the transfer mold process.

The encapsulant 420 may cover the semiconductor chip 200 and may seal the semiconductor chip 200 and the bump structures 300 from surroundings, so that the semiconductor chip 200 and the bump structures 300 may be much more stably bonded to the package board 100. For example, the encapsulant 420 may include the epoxy mold compounds, EMC, similar to the under-fill mold 410. Various thermal dissipaters (not shown) may be arranged on the encapsulant 420, so that the driving heats from the semiconductor chip 200 may be sufficiently dissipated outwards by the thermal dissipater.

The under-fill mold 410 and the encapsulant 420 may be individually provided on the package board 100 by a respective process, or may be simultaneously provided by a single process such as the transfer mold process. When conducting the transfer mold process, the liquefied epoxy mold compounds, EMC, may flow into cavity of the transfer mold in which the chip-board combination is located and the space around the semiconductor chip 200 including the gap space, S, may be filled with the epoxy mold compounds, EMC. Thus, the under-fill mold 410 in the gap space, S, and the encapsulant 420 enclosing the semiconductor chip 200 may be simultaneously formed along the surface of the semiconductor chip 200 by the transfer mold process.

According to the example embodiments of the semiconductor package, a plurality of the gap adjusting bumps 330 may be arranged on the upper insulation pattern 120 of the package board 100 along the peripheral portion of the semiconductor chip 200. Thus, although the semiconductor chip 200 may be excessively compressed toward the package board 100 in the process for forming the molding layer 400, the minimal gap distance Dmin may be maintained between the semiconductor chip 200 and the package board 100. Therefore, the solid fillers in the epoxy mold compounds, EMC, may be sufficiently provided into the gap space, S, between the semiconductor chip 200 and the package board 100 and the bonding force of the semiconductor chip 200 to the package board 100 may be improved in the flip chip structure.

Hereinafter, the method of manufacturing the semiconductor package 500 will be described in detail.

FIGS. 4 to 9 are cross-sectional views illustrating exemplary processing steps for a method of manufacturing the semiconductor package shown in FIG. 1.

Referring to FIG. 4, the semiconductor chip 200 may be provided by a semiconductor fabrication process in such a way that a plurality of chip pads 211 may be arranged on an active face of the semiconductor chip 200 and the active face may be covered with a passivation pattern 220 through which the chip pads 211 may be exposed.

For example, the semiconductor chip 200 may include a chip body 210 and the passivation pattern 220. The chip body 210 may include a semiconductor substrate such as a silicon wafer and a plurality of integrated circuit devices on the substrate. A plurality of the chip pads 211 may be on a top surface of the chip body 210 and the passivation pattern 220 may cover the chip body 210 in such a way that the chip pads 211 may be exposed through the passivation pattern 220. The semiconductor chip 200 may include a memory chip such as DRAM devices and flash memory devices and a logic chip. The chip pad 211 may include a conductive material such as copper (Cu) and aluminum (Al) and the passivation pattern 220 may include a resin such as photosensitive polyimide.

For example, a metal layer may be formed on the chip body 210 by a sputtering process or a thermal evaporation process and then may be patterned into the chip pad 211. Although not shown in figures, the chip pad may be electrically connected to the integrated circuit device of the semiconductor chip 200 and may be electrically insulated from neighboring chip pad by a chip insulation pattern 212.

The passivation pattern 220 may cover the active face of the semiconductor chip 200 and may absorb external forces from surroundings to the semiconductor chip 200. In the present example embodiment, a passivation layer may be formed on the chip pad 211 and the chip insulation pattern 212 by a spin coating process and then may be patterned by a photolithography process in such a way that the chip pads 211 may be exposed through the chip insulation pattern 212.

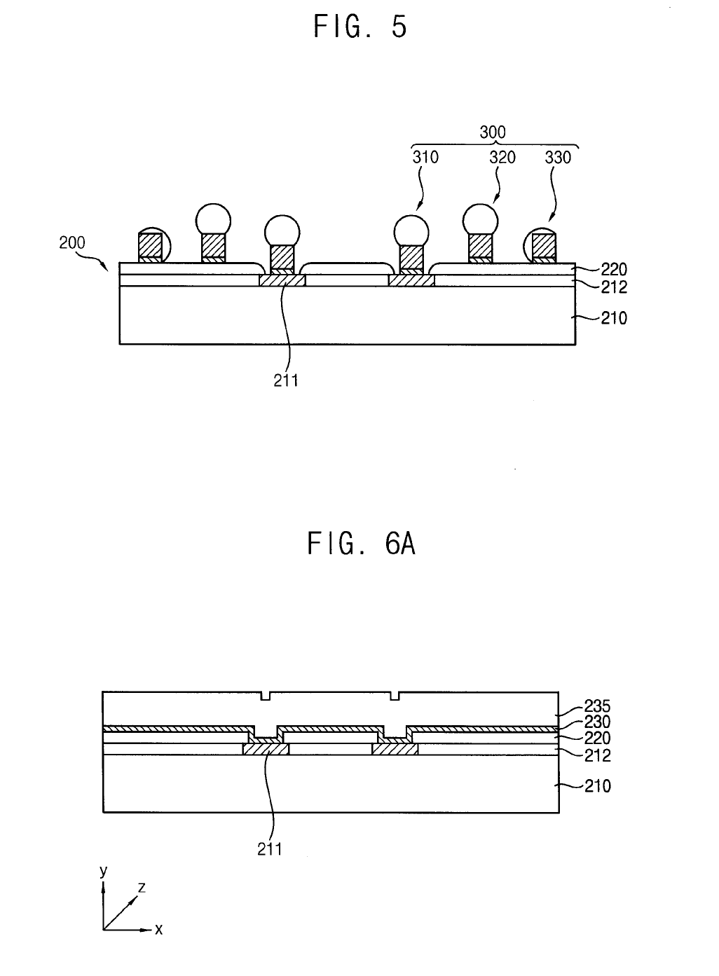

Referring to FIG. 5, the bump structure 300 may be formed on the semiconductor chip 200. The bump structure 300 may include a plurality of protruding connecting bumps 310 bonded to the chip pads 211, respectively, a plurality of protruding supporting bumps 320 bonded to the passivation pattern 220 and a plurality of slender-shaped gap adjusting bumps 330 bonded to the passivation pattern 220

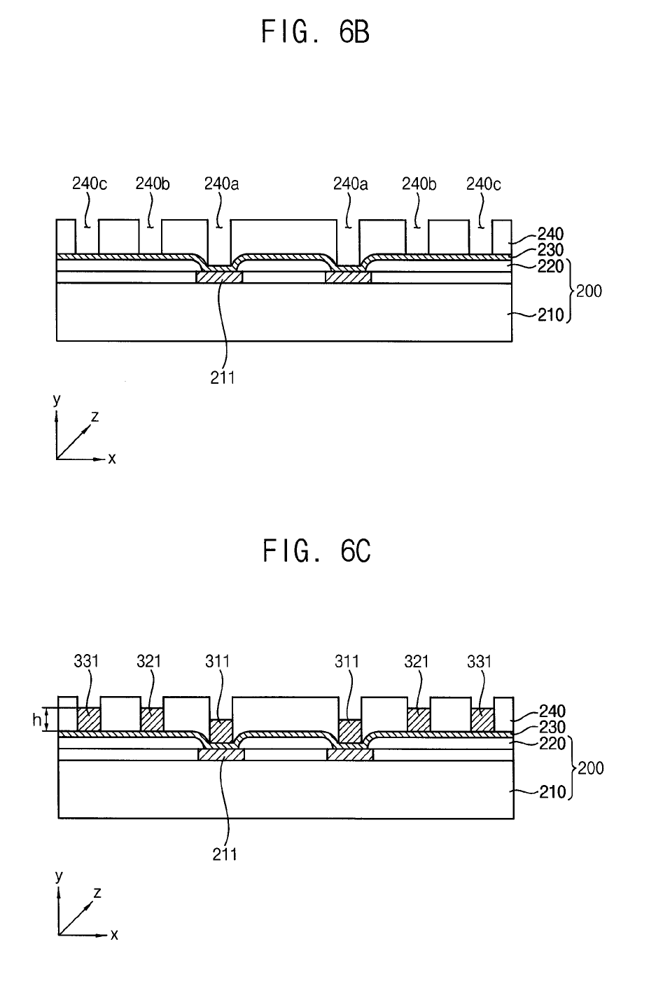

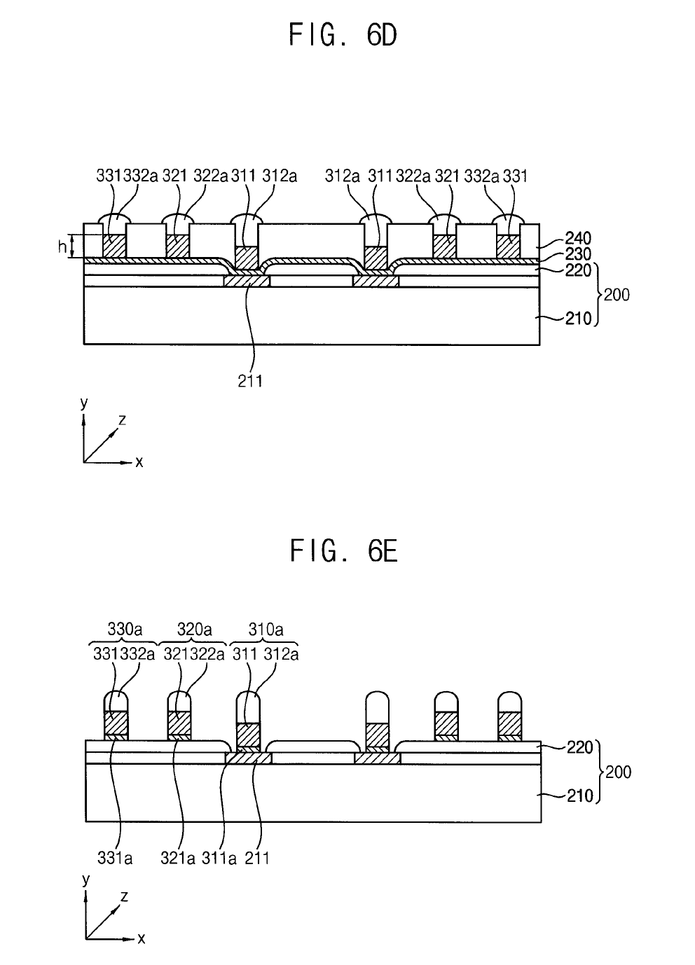

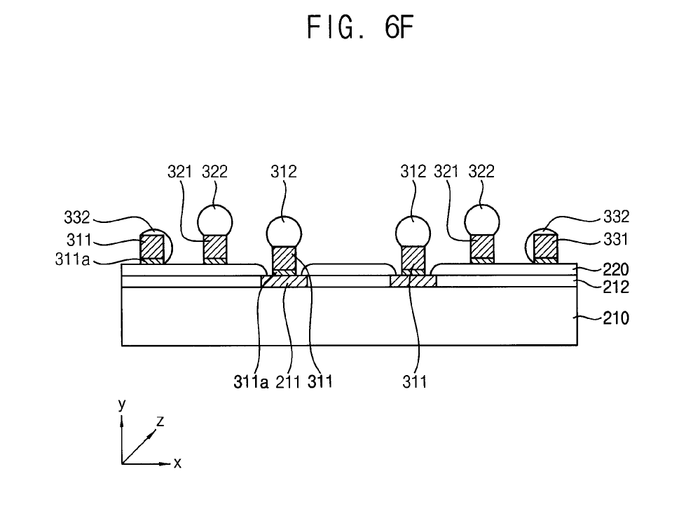

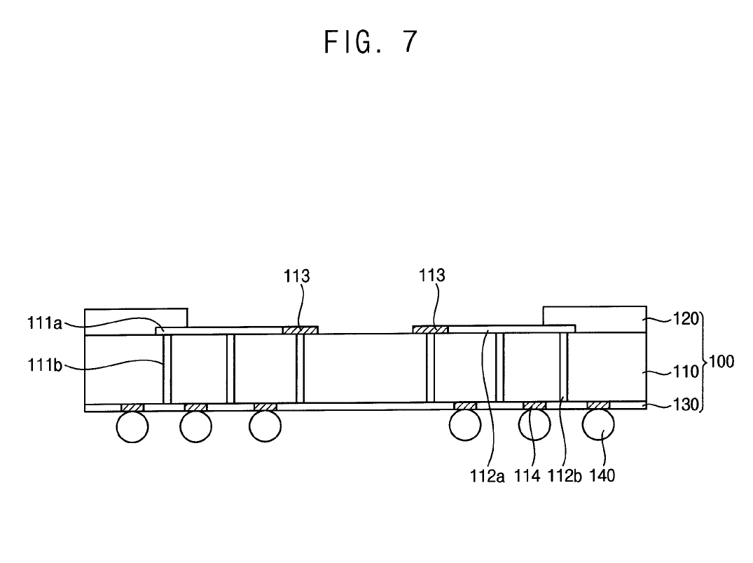

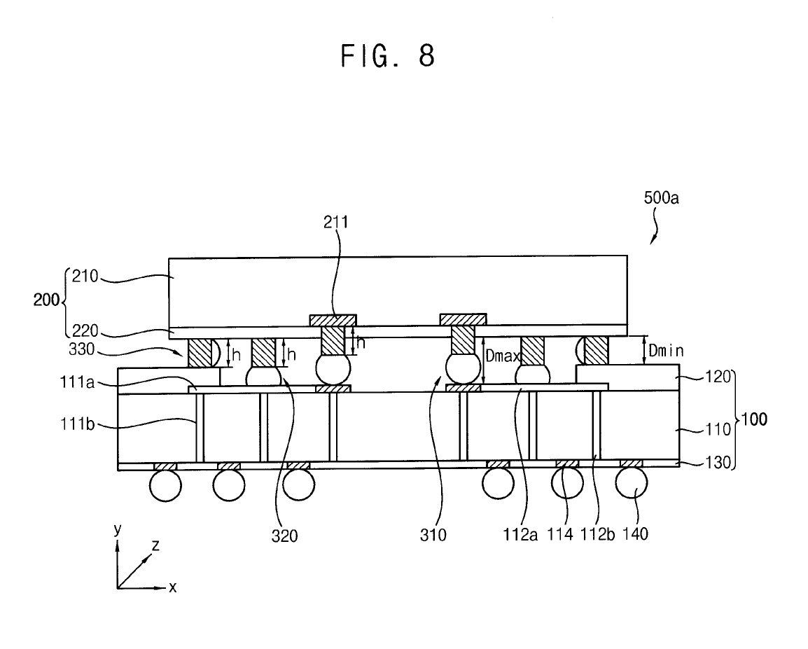

FIGS. 6A to 6F are cross-sectional views illustrating an exemplary embodiment of processing steps for a method of forming the bump structure on the semiconductor chip shown in FIG. 5.

Referring to FIG. 6A, a seed layer 230 and a mask layer 235 may be sequentially formed on the chip pads 211 and the passivation pattern 212.

The seed layer 230 may function as a seed in a subsequent electroplating process for forming a conductive layer. The seed layer 230 may include any one material selected from the group of titanium (Ti), copper (Cu), titanium tungsten (TiW) and combinations thereof. The seed layer 230 may be formed by one of chemical vapor deposition (CVD) process, physical vapor deposition (PVD) process and an atomic layer deposition (ALD) process or another process deemed appropriate. A bather layer (not shown) may be formed between the seed layer 230 and the chip pad 211, and may provide for preventing the diffusion of conductive materials into the chip pad 211. The mask layer 235 may include a photoresist layer.

Referring to FIG. 6B, the mask layer 235 may be patterned into a mask pattern 240 having a first opening 240a through which the seed layer 230 on the chip pad 211 may be partially exposed, a second opening 240b through which the seed layer 230 on the passivation pattern 220 may be partially exposed and a slender-shaped recess 240c through which the seed layer 230 on the passivation pattern 220 may be partially exposed into a slender shape.

The mask layer 235 may be patterned into the mask pattern 240 by a photolithography process to provide the first opening 240a and the second opening 240b and the recess 240c.

In the present exemplary embodiment, the first and the second openings 240a and 240b may be formed into a cubic pillar shape or a cylindrical shape and the recess 240c may be formed into the slender shape. Thus, the seed layer 230 on the chip pad 211 may be exposed through the first opening 240a in the pillar or the cylindrical shape and the seed layer 230 on the passivation pattern 220 slightly off from the chip pad 211 may also be exposed through the second opening 240b in the same pillar or the cylindrical shape. In contrast, a portion of the seed layer 230 disposed over the passivation pattern 220 may be exposed through the recess 240c in the slender shape having a length, L, that extends in a third direction, Z, substantially greater than a width, W, extends in a first direction, X.

For example, the ratio of length to the width, W, of the slender-shaped recess 240c may be in a range of about three (3) to about five (5).

Referring to FIG. 6C, first conductive materials may be supplied into the first opening 240a and the second opening and 240b and into the recess 240c, thereby forming a first pillar body 311 in a lower portion of the first opening 240a, a second pillar body 321 in a lower portion of the second opening 240b and a slender body 331 in a lower portion of the recess 240c.

The first pillar body 311 and the second pillar body 321 may be spaced apart slightly from each other, thus the connecting bumps 310 and the supporting bumps 320 may be spaced apart from each other by a fine pitch. In contrast, the slender body 331 may be shaped into a rod having a relatively long length along the third direction, Z, thus the gap adjusting bump 330 may be shaped into a slender bump having the same length at the peripheral portion of the semiconductor chip 200. For example, the first and the second pillar bodies 311 and 321 and the slender body 331 may be formed by one of an electroplating process, a CVD process and a PVD process.

During assembly, the first conductive materials may be simultaneously supplied to the first opening 240a and the second opening 240b, and thus a top end portion of the first pillar body 311 may be lower than that of the second pillar body 321, and may be as much as the thickness of the passivation pattern 220. In addition, since the recess 240c may be larger than the first opening 240a and the second opening 240b, the first conductive materials may be supplied for a longer time than the first and the second openings 240a and 240b. In the present embodiment, the recess 240c may be formed into such a size that the supplying time of the first conductive materials to the recess 240c may be extended to several times of that to the first and the second openings 240a and 240b in order that a top surface of the slender body 331 may be coplanar with top surfaces of the first and the second pillar bodies 311 and 321.

Therefore, the first pillar body 311 and the second pillar body 321 and the slender body 331 may be formed to have the same height, H, in such a way that the top surface of the second pillar body 321 and the top surface of the slender body 331 may be coplanar with each other and may be the top surface of the slender body 331 and may be higher than the top surface of the first pillar body 311 as much as the thickness of the passivation pattern 220. In the present example embodiment, the first conductive material may include copper (Cu) and aluminum (Al) and the height, H, of the first and the second pillar bodies 311 and 321 and the slender body 331 may be in a range of about 25 μm to about 30 μm.

Referring to FIG. 6D, second conductive materials may be supplied into the first opening 240a and the second opening 240b and into the recess 240c, thereby forming a first solder 312a in an upper portion of the first opening 240a, a second solder 322a in an upper portion of the second opening 240b and a third solder 332a in an upper portion of the recess 240c.

In some embodiments, when the semiconductor chip 200 is mounted onto the package board 100, the second conductive materials may sufficiently bond the first pillar body 311 and the second pillar body 321 to the circuit pattern of the package board 100 while electrically connecting the contact pad 113 with the first pillar body 311. Thus, when the liquefied epoxy mold compounds, EMC, may flow through the gap space between the semiconductor chip 200 and the package board 100 in the transfer mold process, failure of bonding between the first pillar body 311 and the contact pad 113 and between the second pillar body 321 and the wiring line 111a, 112a of the circuit pattern may be sufficiently prevented due to a bonding force of the second conductive materials.

Examples of the second conductive materials may include copper (Cu), nickel (Ni), silver (Ag), gold (Au), lead (Pb), platinum (Pt), tin (Sn), and others as deemed appropriate. Those materials may be used alone or in combinations thereof. The first, second and third solders 312a, 322a and 332a may be formed one of an electroplating process, an electroless plating process, a chemical vapor deposition (CVD) process and a physical vapor deposition (PVD) process.

In the present example embodiment, the first, second and third solders 312a, 322a and 332a may comprise an ally of tin (Sn) and lead (Pb) that may be filled into the upper portion of the first and the second openings 240a and 240b and the recess 240c by an electroplating process.

Referring to FIG. 6E, the mask pattern 240 may be removed from the seed layer 230 and then the seed layer under the mask pattern 240 may also be removed from the passivation pattern 220, so that the seed layer 230 may remain just under the first and the second pillar bodies 311a and 321a and under the slender body 331a as the first to the third seed pattern 311a, 321a, 331a. Thus, the first seed pattern 311a may make contact with chip pad 211 and the first pillar body 311 may be positioned on the first seed pattern 311a and the first solder 312a may be positioned on the first pillar body 311, thereby forming a preliminary connecting bump 310a bonding to the chip pad 211. In the same way, the second seed pattern 321a may make contact with the passivation pattern 220 and the second pillar body 321 may be positioned on the second seed pattern 321a and the second solder 322a may be positioned on the second pillar body 321, thereby forming a preliminary supporting bump 320a bonding to the passivation pattern 220. In addition, the third seed pattern 331a may make contact with the passivation pattern 220 in a rod shape extending along the third direction z and the slender body 331 may be positioned on the third seed pattern 331a and the third solder 332a may be positioned on the slender body 331, thereby forming a preliminary gap adjusting bump 330a bonding to the passivation pattern 220 in the slender shape.

For example, the mask pattern 240 may be removed from the seed layer 230 by an etching process or an ashing process and then the seed layer 230 may be partially removed from the passivation pattern 220 by a dry etching process such as a reactive ion etch (RIE) process. In the present example embodiment, the mask pattern 240 may be sufficiently removed from the seed layer 230 by the ashing process since the mask pattern 240 may include a photoresist pattern.

Therefore, the mask pattern 240 may be removed from the semiconductor chip 200 and the seed layer 230 may remain just only under the first and the second pillar bodies 311 and 321 and under the slender body 331, thereby forming the first to third seed patterns 311a, 321a and 331a.

Thus, the preliminary connecting bump 310a may be bonded to the chip pad 211 and the preliminary supporting bump 320a and the preliminary gap adjusting bump 330a may be bonded to the passivation pattern 220.

As described above, the preliminary connecting bump 310a may be lower than the preliminary supporting bump 320a and the preliminary gap adjusting bump 330a. In addition, the preliminary gap adjusting bump 330a may be shaped into a slender member having a ratio of length to width in a range of about three to five according to the shape of the recess 240c.

Referring to FIG. 6F, a heat treatment may be performed to the preliminary connecting bump 310a, the preliminary supporting bump 320a and the preliminary gap adjusting bump 330a, thereby forming the connecting bump 310 having a first solder ball 312 on the first pillar body 311, the supporting bump 320 having a second solder ball 322 on the second pillar body 321 and the gap adjusting bump 330 having a sidewall solder member 332 on a sidewall of the slender body 331. The first solder 312a and the second solder 322a may be solidified into a ball shape in the heat treatment and may be transformed into the first solder balls 312 and second solder balls 322 and the third solder 332a may flow down along the sidewall of the slender body 331 in the heat treatment and may be formed into the sidewall solder member 332.

For example, the heat treatment may include a reflow process at a temperature greater than a melting point of the first solder 312a, the second solder 322a or the third solder 332a under an atmospheric pressure and under a nitrogen atmosphere. In the present embodiment, the reflow process may be applied to the first solder 312a, the second solder 322a or the third solder 332a for about one minute at temperature more than or equal to about 260 degrees Celsius (° C.).

In case that the first solder 312a and second solder 322a may have high fluidity due to the reflow process, the first solder 312a and the second solder 322a may solidify into the ball shape on the first and the second pillar bodies 311 and 321, respectively, due to a surface tension of the first and the second solders 312a and 322a. In contrast, when the third solder 332a may have high fluidity due to the reflow process, the third solder 332a may flow along the sidewall of the slender body 331 without solidifying, because the sidewall of the slender body 331 may be sufficiently large. Thus, the third solder 332a may be hardened into the sidewall solder member 332 after the reflow process and a little bit of the third solder 332a may remain on the top surface of the slender body 331.

Accordingly, the connecting bump 310 may be formed into such a configuration that the first pillar body 311 may be bonded to the chip pad 211 and the first solder ball 312 may be positioned on the first pillar body 311 and the supporting bump 320 may be formed into such a configuration that the second pillar body 321 may be bonded to the passivation pattern 220 and the second solder ball 322 may be positioned on the second pillar body 321. In contrast, the gap adjusting bump 330 may be formed into such a configuration that the slender body 331 may be bonded to the passivation pattern 220 at the peripheral portion of the semiconductor chip 200 and the sidewall solder member 332 may be positioned on the sidewall of the slender body 331.

Referring to FIG. 7, a package board 100 may be provided in such a configuration that at least a circuit pattern 111 and 112, at least a contact pad 113 and an insulation pattern 120 may be formed on the core 110 and the circuit pattern 111 and 112 may be partially covered with the insulation pattern 120. The circuit pattern may include at least a wiring line 111a and 112a that may be connected to the contact pad 113 and thus the contact pad and portions of the wiring lines 111a and 112a around the contact pad 113 may be exposed through the insulation pattern 120. The rest of the wiring lines 111a and 112a relatively far from the contact pad 113 may be covered with the insulation pattern 120.

In the present example embodiment, the package board 100 may include a printed circuit board (PCB) in which a plurality of thin circuit patterns may be formed on a single face or both faces of the core 110. The circuit pattern may include a first pattern 111 for data transfer and a second pattern for power apply or an electrical earth.

The circuit pattern may be formed into a single pattern or a multilayer pattern on the core 110 and may include a wiring line 111a or 112a and a board via 111b or 112b connecting the wiring lines 111a or 112a penetrating through the core 110. Thus, the board via 111b or 112b may be prepared when the circuit patterns may be provided on both of an upper face and a lower face of the core 110.

In the present example embodiment, the contact pad 113 may be formed on the upper face of the core 110 and may be exposed through an upper insulation pattern 120. The board pad 114 may be formed on the lower face of the core 110 and may be exposed through a lower insulation pattern 130. Particularly, the contact pad 113 and the wiring lines 111a and 112a around the contact pad 113 may be exposed through the upper insulation pattern 120, and thus the rest of the wiring lines 111a and 112a may be covered with the upper insulation pattern 120. The area of the core 110 in which the contact pad 113 and the wiring lines 111a and 112a around the contact pad 113 may be totally exposed through the upper insulation pattern 120 and thus the contact pad 113 and the wiring lines 111a and 112a around the contact pad 113 may be exposed through the same chip interface area CIA. In contrast, the contact pad 113 and the wiring lines 111a and 112a may be individually exposed through a respective opening of the upper insulation pattern 120.

Referring to FIG. 8, the semiconductor chip 200 may be mounted onto the package board 100 in such a manner that the connecting bump 310 may be connected to the contact pad 113 and the supporting bump 320 may be connected to the exposed wiring lines 111a and wiring lines 112a while the gap adjusting bumps 330 may be arranged on the insulation pattern 120, thereby forming a chip-board combination 500a having a gap space between the semiconductor chip 200 and the package board 100 at a minimal gap distance Dmin corresponding to a height of the gap adjusting bump 330.

The semiconductor chip 200 may be mounted onto the package board 100 in a flip chip structure by using a chip mounting apparatus.

For example, the bump structure 300 may be formed on the semiconductor chip 200 by a wafer level packaging process and each of the semiconductor chips 200 may be extracted from the wafer level package. Then, the bump structure 300 may be emerged into a flux tank in such a way that the bump structure 300 may be sufficiently coated with the flux. The package board 100 may be secured to a board transfer bed of the chip mounting apparatus. The semiconductor chip 200 coated with the flux may be transferred and arranged over the package board 100 and then may be move downwards to the package board 100, thereby mounting on the package board 100.

In such a case, the semiconductor chip 200 may be positioned over the package board 100 in such a way that the connecting 310 may be arranged with the contact pad 113 and the supporting bump 320 may be arranged with the wiring lines 111a and 112a while the gap adjusting bump 330 may be located on the upper insulation pattern 120 at the peripheral portion of the semiconductor chip 200.

In the present example embodiment, the package board 100 may include a large-scaled mother PCB together with a number of divided mounting areas and a number of the semiconductor chips 200 may be sequentially or simultaneously mounted to each mounting area of the package board 100, respectively. When the semiconductor chips 200 may be mounted onto all of the mounting areas of the package board 100, the package board 100 may move to an adhesive chamber of the chip mounting apparatus and a heat treatment such as a soldering process may be performed to the semiconductor chips 200. As a result of the heat treatment, the semiconductor chips 200 may be bonded to the package board 100 at each mounting area, thereby forming the chip-board combination 500a.

In the chip-board combination 500a, the connecting bump 310 and the supporting bump 320 may be shaped into the pillar in the chip interface area CIA, while the gap adjusting bump 330 may be shaped into the slender extending along the third direction z between the upper insulation pattern 120 and the passivation pattern 220.

Particularly, when the bump structure 300 may be bonded to the package board 100 by a soldering process, the reflow process for forming the bump structure on the semiconductor chip 200 may be omitted.

In such a case, the semiconductor chip 200 including the first to third solders 312a,322a,332a may be formed into the flip chip structure without the reflow process for forming the first and second solder balls 312 and 322 and the sidewall solder member 332. When the heat treatment such as the solder process may be performed to the flip chip structure, the reflow process for forming the first and second solder balls 312 and 322 and the sidewall solder member 332 may be conducted simultaneously with the solder process.

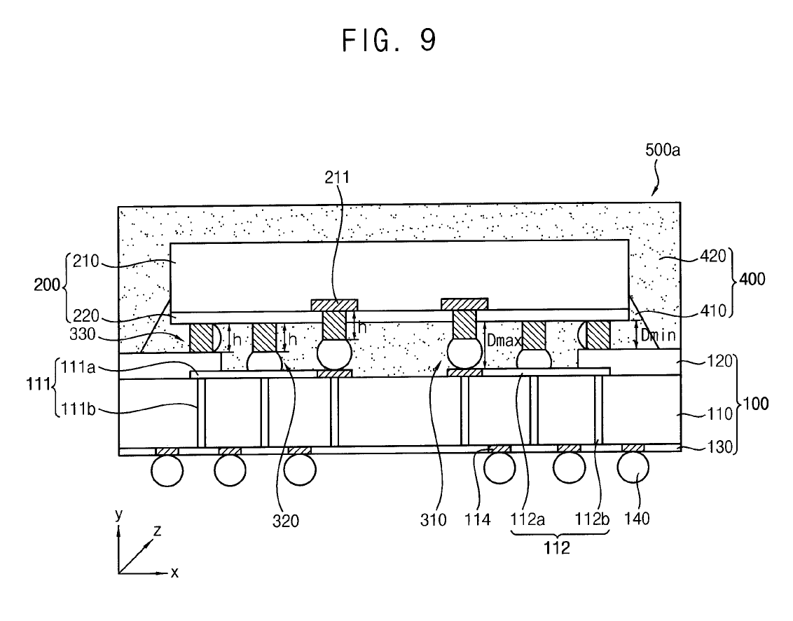

Referring to FIG. 9, a transfer mold process may be conducted to the chip-board combination 500a, thereby forming a molded under-fill (MUF) 410 in the gap space S simultaneously with an encapsulant 420 enclosing the semiconductor chip 200. Therefore, the semiconductor chip 200 may be spaced apart from the chip board 100 at a minimal gap distance Dmin corresponding to the height h of the gap adjusting bump 330, while the bump structure 300 may be formed to have a fine pitch. Accordingly, mold materials including minute fillers may be sufficiently flow into the gap space S to thereby reinforce the bonding force between the semiconductor chip 200 and the package board 100 while preventing the bridge defects caused by the solder compression of neighboring bumps.

The chip-board combination 500a may be located in a mold for the transfer mold process and may be compressed under a molding pressure and a molding temperature. Then, the liquefied EMC may be supplied into the mold and thus the liquefied EMC may flow around the semiconductor chip 200 as well as flowing through the gap space S between the semiconductor chip 200 and the package board 100. After completing the transfer mold process, the EMC may be hardened in the gap space S and around the semiconductor chip 200 on the package board 100, thereby forming the mold layer 400 including the molded under-fill (MUF) 410 and the encapsulant 420. Therefore, the molded under-fill (MUF) 410 in the gap space S and the encapsulant 420 around the semiconductor chip 200 may be formed on the package board 100 simultaneously with each other in a single transfer mold process.

While the present example embodiment discloses that the MUF 410 may be integrally formed with the encapsulant 420 in the same process, the MUF 410 and the encapsulant 420 may be individually formed by a respective process.

Particularly, when the package board may be provided as the large-scaled PCB and a plurality of the semiconductor chips 200 may be mounted on the large-scaled PCB, the MUF between a plurality of the semiconductors and the package board may be simultaneously formed by the transfer mold process together with the encapsulant enclosing the semiconductor chips.

When conducting the transfer mold process, the semiconductor chip 200 may be excessively compressed towards the package board 100. However, the semiconductor chip 200 may be spaced apart from the package board 100 by the minimal gap distance Dₘᵢₙ due to the gap adjusting bump 330 in spite of the compressive force to the semiconductor chip 200 in the transfer mold process. Since the minimal gap distance Dₘᵢₙ may be varied according to the height of the gap adjusting bump 330, the gap adjusting bump 330 may be formed in such a viewpoint whether the process conditions of the transfer mold process may be sufficiently satisfied. For example, when the liquefied EMC may include the minute fillers having a diameter of about 25 μm to about 30 μm.

The minute fillers in the liquefied EMC may reinforce the bonding force between the semiconductor chip 200 and the package board 100, so that the excessive compression of the semiconductor chip 200 to the package board 100 in the transfer mold process may give rise to the gap distance reduction between the semiconductor chip 200 and the board 100 and thus may result in the insufficient supply of the fillers into the gap space S. However, the gap adjusting bump 330 in the present example embodiment may assure the minimal gap distance Dₘᵢₙ between the semiconductor chip 200 and the board 100 in spite of the excessive compressive force in the transfer mold process, which may sufficiently prevent the deficiency of the fillers in the gap space S in the mold transfer process.

Since the conventional liquefied EMC may include the minute fillers having a diameter smaller than about 24 μm, the slender body 331 having the height of about 25 μm to about 30 μm may allow the minute fillers in the liquefied EMC to sufficiently flow in the gap space S and thus the MUF may be formed to have sufficient fillers.

Thereafter, the large-scaled PCB may be cut into pieces along a cutting line package by the mounting area, thereby forming the semiconductor package 500.

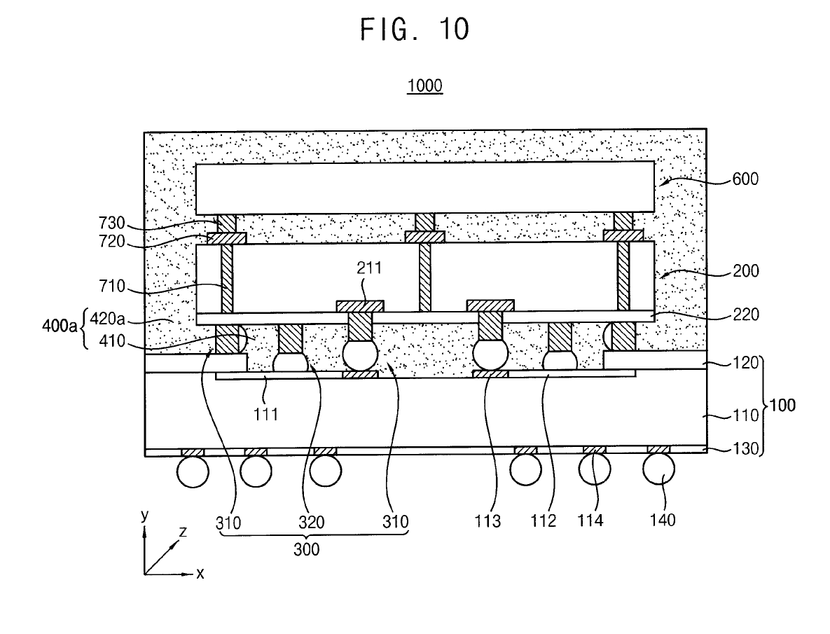

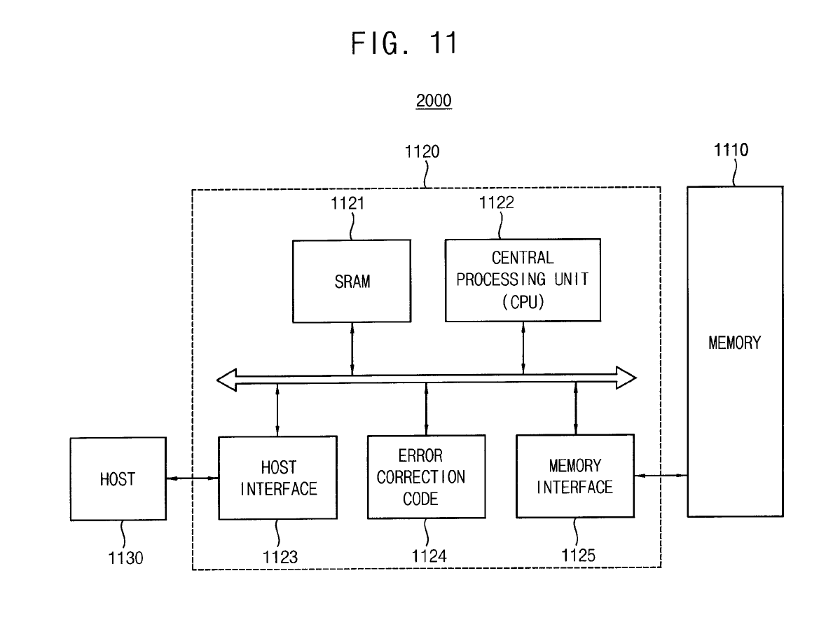

FIG. 10 is a cross-sectional view illustrating another exemplary embodiment of the semiconductor package in accordance with the teachings herein.

Referring to FIG. 10, a multi stack package 1000 may be disclosed to include the gap adjusting bump 330, so that the minimal gap distance may be maintained between the semiconductor chip and the package board in the multi stack package 1000.

The multi stack package 1000 may include an additional semiconductor chip 600 on the semiconductor package 500 in such a configuration that the semiconductor chip 600 and the semiconductor chip 200 may be sealed from surroundings by a modified mold layer 400a. Hereinafter, the semiconductor chip 200 may be referred to as first chip and the additional semiconductor chip 600 may be referred to as second chip.

While the present example embodiment discloses that a single additional semiconductor chip 600 is added to the semiconductor package 500, two or more additional semiconductor chips would also be added to the semiconductor chip 500.

The multi stack package 1000 may include the second semiconductor chip 600 on the first semiconductor chip 200 and at least an inter-chip connector 700 electrically connecting the first semiconductor chip 200 and the second semiconductor chip 600. Thus, the multi stack package 1000 may include the same bump structure 300 and the first semiconductor chip 200 and the second semiconductor chip 600 may be covered with the modified mold layer 400a on the package board 100. The bump structure 300 may also include the connecting bump 310, the supporting bump 320 and the gap adjusting bump 330.

The package board 100, the first semiconductor chip 200 and the bump structure 300 may have substantially the same structures as those in the semiconductor chip 500 described in detail with reference to FIG. 1. Thus, any further detailed descriptions on the package board 100, the first semiconductor chip 200 and the bump structure 300 will be omitted hereinafter. The modified mold layer 400a may also have the same compositions and structures as the mold layer 400 in FIG. 1, except that the modified layer 400 may cover the second semiconductor chip 600 as well as the first semiconductor chip 200 on the package board 100.

The second semiconductor chip 600 may include a memory chip such as a flash memory chip and a DRAM chip and the first semiconductor chip 200 may include a memory chip and a control chip.

The inter-chip connector 700 may include a penetration electrode 710 penetrating through at least one of the first and second chips 200 and 600 and an inter-chip bump structure 730 bonded to the penetration electrode 710. In addition, at least a re-directional line 720 may be further provided on the rear face of the first semiconductor chip 200 and may be connected to the penetration electrode 710 and the an inter-chip bump structure 730.

The second semiconductor chip 600 may be connected to the inter-chip bump structure 730 that may be connected to the penetrating electrode 710 through the first semiconductor chip 200 and the penetrating electrode 710 may be connected to the package board 100. Thus, the second semiconductor chip 600 may be electrically connected to the package board 100 via the inter-chip bump structure 730 and the penetrating electrode 710.

While the second semiconductor chip 600 may face downwards and the inter-chip bump structure 730 may be arranged on the active face of the second semiconductor chip 600, any other modifications of the inter-chip bump structure 730 may be allowable according to the requirements of the multi stack package 1000. For example, the inter-chip bump structure 730 may be arranged on a rear face of the second semiconductor chip 600 and an additional penetrating electrode (not shown) may be further provided through the second semiconductor chip 600.

The modified mold layer 400a may include the MUF 410 and a modified encapsulant 420a enclosing the first semiconductor chip 200 and the second semiconductor chip 600 and a gap space, S, between the first semiconductor chip 200 and the second semiconductor chip 600. The MUF 410 and the modified encapsulant 420a may also be formed integrally with each other by a single transfer mold process.

In the transfer mold process, the first semiconductor chip 200 may be sufficiently spaced apart from the package board 100 at the minimal gap distance, Dₘᵢₙ, corresponding to the height, H, of the gap adjusting bump 330. Accordingly, the mold materials including minute fillers may be sufficiently flow into the gap space, S, to thereby reinforce the bonding force between the first semiconductor chip 200 and the package board 100 while preventing the bridge defects caused by the solder compression of neighboring bumps, thereby increasing the reliability of the multi stack package 1000.

FIG. 11 is a block diagram illustrating non-limiting aspects of a memory card 2000. The memory card 2000 includes a semiconductor package fabricated in accordance with embodiments as disclosed herein. In some embodiments, the memory card includes the semiconductor package 500 as shown in FIG. 1 or the multi stack package 1000 as shown in FIG. 10.

The memory card 2000 may include a host 1130, a memory unit 1110 for storing data, and a memory controller 1120 for controlling data transfer between the memory unit 1110 and the host 1130.

The memory unit 1110 may include a plurality of memory chips to which electronic data may be transferred from the external host 1130. The electronic data may be stored in the memory unit 1110. The memory chips included in the memory unit 1110 may include, for example, a plurality of DRAM chips or flash memory chips. The host 1130 may include various external electronic systems for processing the electronic data. For example, the host 1130 may include a computer system and a mobile system of which the data storage space may be extendable.

The memory controller 1120 may be connected to the host 1130 and may control data transfer between the memory unit 1110 and the host 1130.

The memory controller 1120 may include a central process unit (CPU) 1122 for processing the control of data transfer between the host 1130 and the memory unit 1110 and a static random access memory (SRAM) device 1121 as an operational memory device for the CPU 1122. Further, the memory controller 1120 may include a host interface 1123 having a data transfer protocol of the host 1130, an error correction code 1124 for detecting and correcting errors of the electronic data in the memory unit 1110 and a memory interface 1125 connected to the memory unit 1110.

The SRAM 1121 and the CPU 1122 may be combined with each other and thus may be provided as the multi stack package 1000 shown in FIG. 10. That is, the CPU 1122 may function as the first semiconductor chip 200 and the SRAM 1121 may function as the second semiconductor chip 600 in the multi stack package 1000. In such a case, the minimal gap distance, Dₘᵢₙ, between the first semiconductor chip 200 and the package board 100 may be sufficiently maintained by the gap adjusting bump 330, thereby sufficiently supplying the minute fillers in the gap space. The memory card 2000 may exhibit improved reliability due to the gap adjusting bump 330.

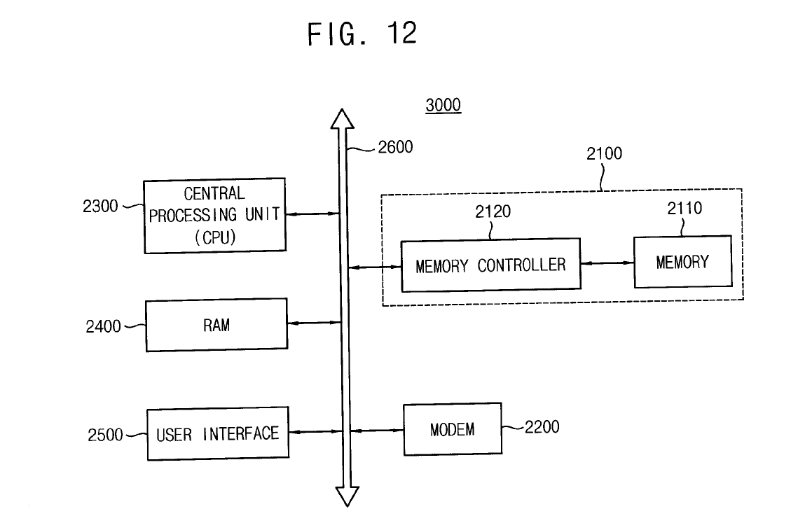

FIG. 12 is a block diagram illustrating aspects of an exemplary electronic system 3000 that includes the semiconductor package shown in one of FIGS. 1 and 10.

Referring to FIG. 12, the electronic system 3000 may include a memory system 2100 that includes the semiconductor package 500 as shown in FIG. 1 or a multi stack package 1000 as shown in FIG. 10. The electronic system 3000 may be one of various mobile systems (e.g., a smart phone and a tablet computer) a traditional computer systems (e.g., a laptop computer system and a desktop computer system, simply referred to as a “personal computer (PC)”), or another type of device including specialized equipment such as a radio (for example, a global positioning system (GPS) receiver, part of a communications network) as well as many others.

The electronic system 3000 may include the memory system 2100 and a MODEM 2200, a CPU 2300, a RAM device 2400 and a user interface 2500 that may be electrically connected to the memory system 2100 via a system bus line 2600.

The memory system 2100 may include a memory unit 2110 and a memory controller 2120. The memory unit 2110 and the memory controller 2120 may have the same structure as the memory card 2000 shown in FIG. 11, and thus the memory unit 2110 and the memory controller 2120 may incorporate aspects of the same packages described in detail with reference to FIGS. 1 and 10. The memory system 2100 may store electronic data that may be processed at the CPU 2300 or may be transferred from the external data source.

Thus, the bonding force and bridge defects in the semiconductor package 500 or the multi stack package 1000 may be substantially prevented due to the gap adjusting bump 330, thereby substantially increasing operational reliability of the electronic system 3000 including the memory system 2100.

The electronic system 3000 may be, for example, a memory card, a solid state disk, a camera image sensor and various application chipsets (AP). For example, when the memory system 2100 is used as a solid state disk (SSD), the electronic system 3000 may process and store a relatively great volume of data with relatively high stability and reliability.

The memory system 2100 may be used to store a variety of types of data including computer executable instructions for implementation of a method (also referred to as “software”).

According to the example embodiments of the semiconductor package and of the method of manufacturing the same, a plurality of gap adjusting bumps may be arranged on the package board along the peripheral portion of the semiconductor chip, and thus the semiconductor chip may be spaced apart from the chip board at a minimal gap distance corresponding to the height of the gap adjusting bump. Accordingly, the mold materials including minute fillers may be sufficiently flow into the gap space, S, to thereby reinforce the bonding force between the semiconductor chip and the package board while preventing the bridge defects caused by the solder compression of neighboring bumps in the transfer mold process.

The present example embodiments of the semiconductor package may be applied to various electronic systems including the semiconductor package in which the semiconductor chip may be spaced apart from the package board at the minimal gap distance. Particularly, the semiconductor package may be applied to a storage device and a controller for various electronic communication systems and storage systems for increasing the reliability thereof.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor package comprising:
a package board comprising an circuit pattern and a plurality of contact pads electrically connected to the circuit pattern;
a semiconductor chip having a plurality of chip pads; and
a bump structure comprising a plurality of connecting bumps electrically connected with the semiconductor chip and the circuit pattern and a plurality of gap adjusting bumps bonded to the semiconductor chip and shaped into a slender bar between the semiconductor chip and the package board, the gap adjusting bumps spacing the semiconductor chip from the package board such that a gap space, S, is maintained between the package board and the semiconductor chip.

2. The semiconductor package of claim 1, wherein the semiconductor chip includes a passivation pattern covering an active face thereof and through which the chip pads are exposed and the plurality of gap adjusting bumps comprises at least one slender body connected to the passivation layer and a sidewall solder member arranged on a sidewall of the slender body.

3. The semiconductor package of claim 2, wherein the sidewall of the slender body is shaped into a concave face that is directed to a center of the slender body and is at least partially covered with the sidewall solder member.

4. The semiconductor package of claim 2, wherein each connecting bump includes a first conductive pillar body bonded to a respective chip pad and includes a first solder ball at an end portion of the first pillar body.

5. The semiconductor package of claim 4, wherein the package board includes an insulation pattern covering an upper surface thereof and through which at least one contact pad is exposed and the corresponding connecting bump is bonded to the contact pad via the first solder ball while the gap adjusting bump is interposed between the passivation pattern and the insulation pattern and makes contact with the passivation pattern and the insulation pattern.

6. The semiconductor package of claim 5, wherein the bump structure includes a plurality of supporting bumps bonded to the semiconductor chip and supporting the semiconductor chip on the package board.

7. The semiconductor package of claim 6, wherein the circuit pattern includes at least a wiring line electrically connected to the contact pad and exposed through the insulation pattern and at least one supporting bump includes a second conductive pillar body bonded to the passivation pattern and a second solder ball positioned at an end portion of the second pillar body and bonded to the wiring line.

8. The semiconductor package of claim 7, wherein the circuit pattern is bonded to a single connecting bump and a plurality of the supporting bumps in such a configuration that the contact pad is bonded to the connecting bump and the wiring line is bonded to a plurality of the supporting bumps, and the gap adjusting bumps are arranged on the insulation pattern without any interference with the connecting bumps and the supporting bumps.

9. The semiconductor package of claim 7, wherein the slender body has a height corresponding to the first pillar body and the second pillar body, so that the height of the slender body is provided as the minimal gap distance between the semiconductor chip and the package board.

10. The semiconductor package of claim 9, further comprising an under-fill mold filling the gap space between the semiconductor chip and the package board.

11. The semiconductor package of claim 10, wherein the minimal gap distance, Dₘᵢₙ, is in a range of between 25 μm to 30 μm and the under-fill mold includes a plurality of fillers having a size ranging between 20 μm to 24 μm.

12. A method of manufacturing a semiconductor package, comprising:
providing a semiconductor chip having a plurality of chip pads on an active face and a passivation pattern covering the active face, the chip pads being exposed through the passivation pattern;
forming a bump structure on the semiconductor chip, the bump structure including a plurality of protruding connecting bumps bonded to the chip pads, respectively, a plurality of protruding supporting bumps bonded to the passivation pattern and a plurality of slender-shaped gap adjusting bumps bonded to the passivation pattern;
providing a package board having at least one circuit pattern, at least one contact pad connected to the circuit pattern and an insulation pattern covering the circuit pattern such that the circuit pattern includes a wiring line connected to the contact pad and the contact pad and a portion of the wiring around the contact pad are exposed through the insulation pattern;
mounting the semiconductor chip onto the package board in such a manner that each connecting bump is connected to a corresponding one of the contact pads and the supporting bump is connected to the exposed wiring while the gap adjusting bumps are arranged on the insulation pattern, thereby forming a chip-board combination having a gap space, S, between the semiconductor chip and the package board at a minimal gap distance corresponding to a height of the gap adjusting bump; and
conducting a transfer mold process to the chip-board combination, thereby forming a molded under-fill (MUF) in the gap space simultaneously with an encapsulant enclosing the semiconductor chip.

13. The method of claim 12, wherein forming the bump structure on the semiconductor chip includes:
sequentially forming a seed layer and a mask layer on the chip pads and the passivation pattern;
patterning the mask layer into a mask pattern having a first opening through which the seed layer on the plurality of chip pads is partially exposed, a second opening through which the seed layer on the passivation pattern is partially exposed and a slender-shaped recess through which the seed layer on the passivation pattern is partially exposed into a slender shape;
forming a first pillar body in a lower portion of the first opening, a second pillar body in a lower portion of the second opening and a slender body in a lower portion of the recess;
forming a first solder in an upper portion of the first opening, a second solder in an upper portion of the second opening and a third solder in an upper portion of the recess;
removing the mask pattern and the seed layer under the mask pattern, thereby forming a preliminary connecting bump having a first seed pattern making contact with the respective chip pad, the first pillar body on the first seed pattern and the first solder on the first pillar body, a preliminary supporting bump having a second seed pattern making contact with the passivation pattern, the second pillar body on the second seed pattern and the second solder on the second pillar body, and a preliminary gap adjusting bump having a third seed pattern making contact with the passivation pattern, the third pillar body on the third seed pattern and the third solder on the third pillar body; and
performing a heat treatment to the preliminary connecting bump, the preliminary supporting bump and the preliminary gap adjusting bump, thereby forming the connecting bump having a first solder ball on the first pillar body, the supporting bump having a second solder ball on the second pillar body and the gap adjusting bump having a sidewall solder member on a sidewall of the slender body.

14. The method of claim 13, wherein mounting the semiconductor chip onto the package board includes a soldering process for bonding the first solder ball to the contact pad and for bonding the second solder ball to the wiring line.

15. The method of claim 14, wherein the soldering process is performed simultaneously with the heat treatment.

16. A memory package comprising:
a memory unit comprising a semiconductor package comprising a package board comprising an circuit pattern and a plurality of contact pads electrically connected to the circuit pattern; a semiconductor chip having a plurality of chip pads; and a bump structure having a plurality of connecting bumps electrically connected with the semiconductor chip and the circuit pattern and a plurality of gap adjusting bumps bonded to the semiconductor chip and shaped into a slender bar between the semiconductor chip and the package board, the gap adjusting bumps spacing the semiconductor chip from the package board such that a gap space, S, is maintained between the package board and the semiconductor chip.

17. The memory package as in claim 16, further comprising a memory controller for controlling data transfer between the memory unit and a host.

18. The memory unit as in claim 16, configured as one of a DRAM memory chip and a flash memory chip.

19. The memory unit as in claim 16, configured for use in one of a mobile system, a personal computer and a specialized system.

20. The memory unit as in claim 16, wherein the semiconductor package comprises one of a single stack package and a multi stack package.
